(19) United States
(12) Patent Application Publication
(10) Pub. No.: US 2013/0133720 A1
(43) Pub. Date: May 30, 2013

(54) SOLAR BATTERY MODULE AND MANUFACTURING METHOD THEREOF

(71) Applicants: Shih-Wei Lee, Kaohsiung City (TW); Ming-Hung Lin, Pingtung County (TW); Yao-Tsang Tsai, Tainan City (TW)

(72) Inventors: Shih-Wei Lee, Kaohsiung City (TW); Ming-Hung Lin, Pingtung County (TW); Yao-Tsang Tsai, Tainan City (TW)

(73) Assignee: AXUNTEK SOLAR ENERGY, Pingtung County (TW)

(21) Appl. No.: 13/456,192

(22) Filed: Apr. 25, 2012

(30) Foreign Application Priority Data
Nov. 24, 2011 (TW) 100143090

(51) Int. Cl. H01L 31/05; H01L 31/0224

(52) U.S. Cl. 136/249; 438/98; 257/E31.126

(57) ABSTRACT

A solar battery module includes a substrate, striped metal electrode layers formed alternately on the substrate along a first direction, striped photoelectric transducing layers, striped transparent electrode layers, and electrode lines. Each striped photoelectric transducing layer is formed on the striped metal electrode layer and the substrate along the first direction. Each striped transparent electrode layer is formed on the striped metal electrode layer and the striped photoelectric transducing layer along the first direction. The striped transparent electrode layers and the striped metal electrode layers are in series connection along a second direction. The electrode lines are formed alternately on each striped transparent electrode layer or between each striped photoelectric transducing layer and each striped transparent electrode layer along the second direction. A width of each electrode line is less than an interval between the striped transparent electrode layer and the adjacent striped metal electrode layer.

### BACKGROUND OF THE INVENTION

1. Field of the Invention

The present invention relates to a solar battery module and a manufacturing method thereof, and more specifically, to a thin-film solar battery module utilizing electrode lines to collect current and a manufacturing method thereof.

2. Description of the Prior Art

Please refer to FIG. 1, which is a diagram of a solar battery module 10 in the prior art. The conventional solar battery module 10 includes a substrate 12, a plurality of conductive layers 14, a plurality of photoelectric transducing layers 16 and a plurality of electrode layers 18. A manufacturing method of the conventional solar battery module 10 is forming the conductive layers 14 on the substrate 12, removing parts of the conductive layers 14 to expose parts of the substrate 12, forming the photoelectric transducing layers 16 on the substrate 12 and the conductive layers 14, removing parts of the photoelectric transducing layers 16 to expose parts of the conductive layers 14, forming the electrode layers 18 on the conductive layers 14 and the photoelectric transducing layers 16, and removing parts of the electrode layers 18 to expose parts of the conductive layers 14. Thus, each electrode layer 18 is electrically connected to the corresponding conductive layer 14 for setting a plurality of solar batteries 101 in series connection, so that the conventional solar battery module 10 could generate a greater voltage.

However, since the areas on the solar battery module 10, which are scratched by a laser removing process and a mechanical removing process, are incapable of executing a photoelectric transducing function and are therefore named inactive areas, the aforesaid manufacturing method may reduce the photoelectric transducing efficiency of the solar battery module 10 accordingly due to dimensions of the inactive areas. Although the aforesaid problem could be solved by increasing the width of each solar battery 11 for reducing the dimensions of the inactive areas, this method may additionally increase the resistance of the electrode layer 18 so as to reduce the photoelectric transducing efficiency of the solar battery module 10. Even if a method of increasing the thickness of the electrode layer 18 is further utilized to reduce the resistance of the electrode layer 18, the transmittance of the electrode layer 18 is decreased accordingly so as to influence the overall photoelectric transducing efficiency of the solar battery module 10. Thus, how to manufacturing a solar battery module with a better photoelectric trasnducing efficiency is an important issue of the solar industry.

### SUMMARY OF THE INVENTION

The present invention provides a solar battery module. The solar battery module includes a substrate, a plurality of striped metal electrode layers, a plurality of striped photoelectric transducing layers, a plurality of striped transparent electrode layers, and a plurality of electrode lines. The plurality of striped metal electrode layers is formed alternately on the substrate along a first direction. Each striped photoelectric transducing layer is formed on the corresponding striped metal electrode layer and the substrate along the first direction. Each striped transparent electrode layer is formed on the corresponding striped metal electrode layer and the corresponding striped photoelectric transducing layer along the first direction. The plurality of striped transparent electrode layers and the plurality of striped metal electrode layers are in series connection along a second direction. The plurality of electrode lines is formed alternately on each striped transparent electrode layer or between each striped photoelectric transducing layer and each striped transparent electrode layer along the second direction. A width of each electrode line is less than an interval between the striped transparent electrode layer on each striped metal electrode layer and the adjacent striped metal electrode layer.

The present invention further provides a method for manufacturing a solar battery module. The method includes forming a metal electrode layer on a substrate, removing parts of the metal electrode layer along a first direction to form a plurality of striped metal electrode layers alternately arranged on the substrate, forming a photoelectric transducing layer on each striped metal electrode layer and the substrate, removing parts of the photoelectric transducing layer along the first direction to form a plurality of striped photoelectric transducing layers alternately arranged on the each striped metal electrode layer and the substrate, so as to expose a part of each striped metal electrode layer, forming a plurality of electrode lines alternately arranged on each striped photoelectric transducing layer along a second direction, forming a transparent electrode layer on each striped photoelectric transducing layer and each electrode line, and removing parts of the transparent electrode layer, parts of the electrode lines, and a part of each striped photoelectric transducing layer along the first direction to form a plurality of striped transparent electrode layers alternately arranged on each striped photoelectric transducing layer and each electrode line and expose a part of each striped metal electrode layer, so as to make the plurality of striped metal electrode layers and the plurality of striped transparent electrode layers in series connection along the second direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a solar battery module in the prior art.

FIG. 2 is a partial diagram of a solar battery module according to an embodiment of the present invention.

FIG. 3 is a flowchart of a method for manufacturing the solar battery module in FIG. 2.

FIGS. 4-11 are sectional views of the solar battery module along a second direction in different procedures in FIG. 2.

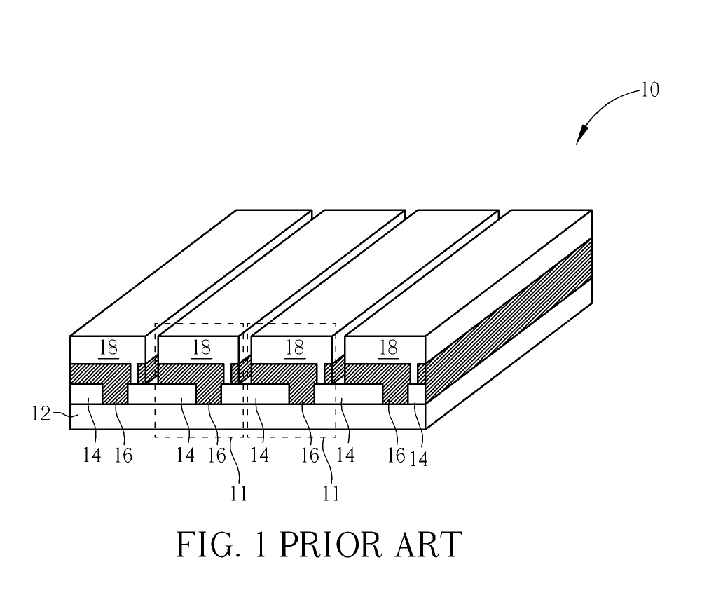

### DETAILED DESCRIPTION

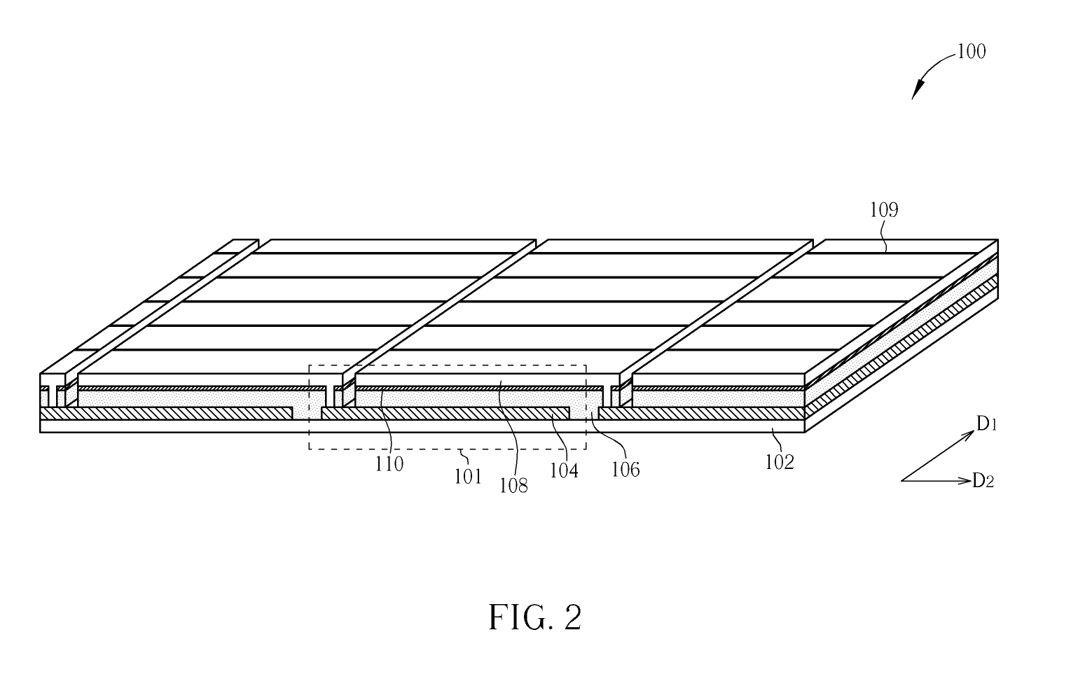

Please refer to FIG. 2, which is a partial diagram of a solar battery module 100 according to an embodiment of the present invention. The solar battery module 100 includes a substrate 102, a plurality of striped metal electrode layers 104 and a plurality of striped photoelectric transducing layers 106. The plurality of striped metal electrode layers 104 is alternately arranged on the substrate 102, and each striped metal electrode layer 104 does not contact the adjacent striped metal electrode layer 104 along a second direction D₂. Each striped photoelectric transducing layer 106 is formed on the corresponding striped metal electrode layer 104 along a first direction D₁, and does not contact the adjacent striped photoelectric transducing layer 106 along the second direction D₂. The first direction D₁ is substantially perpendicular to the second direction D₂.

The solar battery module 100 further includes a plurality of striped transparent electrode layers 108 and a plurality of electrode lines 109. Each striped transparent electrode layer 108 is formed on the striped metal electrode layer 104 along the first direction D₁. The electrode lines 109 are alternately formed on each striped transparent electrode layer 108 along the second direction D₂. In this embodiment, the width of each electrode line 109 is preferably less than the interval between the corresponding striped transparent electrode layer 108 on each striped metal electrode layer 104 and the adjacent metal electrode layer 104, and the interval between two adjacent electrode lines 109 is less than or equal to 13 mm. Accordingly, the solar battery module 100 could be consisted of a plurality of solar batteries 101. The striped photoelectric transducing layer 106 of the solar battery 101 could transform solar energy into electrical power, and the striped metal electrode layer 104 and the striped transparent electrode layer 108 could respectively be a positive electrode and a negative electrode of the solar battery 101 for outputting the electrical power. That is, the plurality of striped metal electrode layers 104 is electrically connected to the plurality of striped transparent electrode layers 108 along the second direction D₂. In other words, the plurality of solar batteries 101 is in series connection along the second direction D₂ which is substantially perpendicular to the first direction D₁. Furthermore, the electrical lines 109 on the striped transparent electrode layers 108 could be utilized as auxiliary electrodes for current collection. In such a manner, an outputting voltage of the solar battery module 100 could be adjusted according to actual demand and the solar battery module 100 could generate a greater current via disposal of electrode lines 109. In addition, the solar battery module 100 further includes a buffer layer 110 disposed between each striped photoelectric transducing layer 106 and each striped transparent electrode layer 108.

Generally, the substrate 102 could be a soda-lime glass. The striped metal electrode layer 104 could be made of molybdenum (Mo) material, Tantalum (Ta) material, Titanium (Ti) material, Vanadium (V) material, or Zirconium (Zr) material. The striped photoelectric transducing layer 106 could be a chalcopyrite structure, such as copper indium selenide, copper indium sulfide (CIS), copper indium gallium selenide (CIGS), or copper indium gallium selenide sulfide (CIGSS). The striped transparent electrode layer 108 could be a conductive layer made of aluminum zinc oxide (AZO) or tin-doped indium oxide (ITO) material. The buffer layer 110 could be made of cadmium sulfide (CdS), zinc sulfide (ZnS) material or indium sulfide (In₂S₃) and intrinsic zinc oxide (ZnO) material. The electrode line 109 could be made of conductive silver paste material or conductive aluminum paste material. The solar battery module 100 could be a thin-film solar battery module. Material of the substrate 102, the striped metal electrode layer 104, the striped photoelectric transducing layer 106, the striped transparent electrode layer 108, the buffer layer 110, and the electrode line 109 is not limited to the above-mentioned embodiment, and depends on design demand.

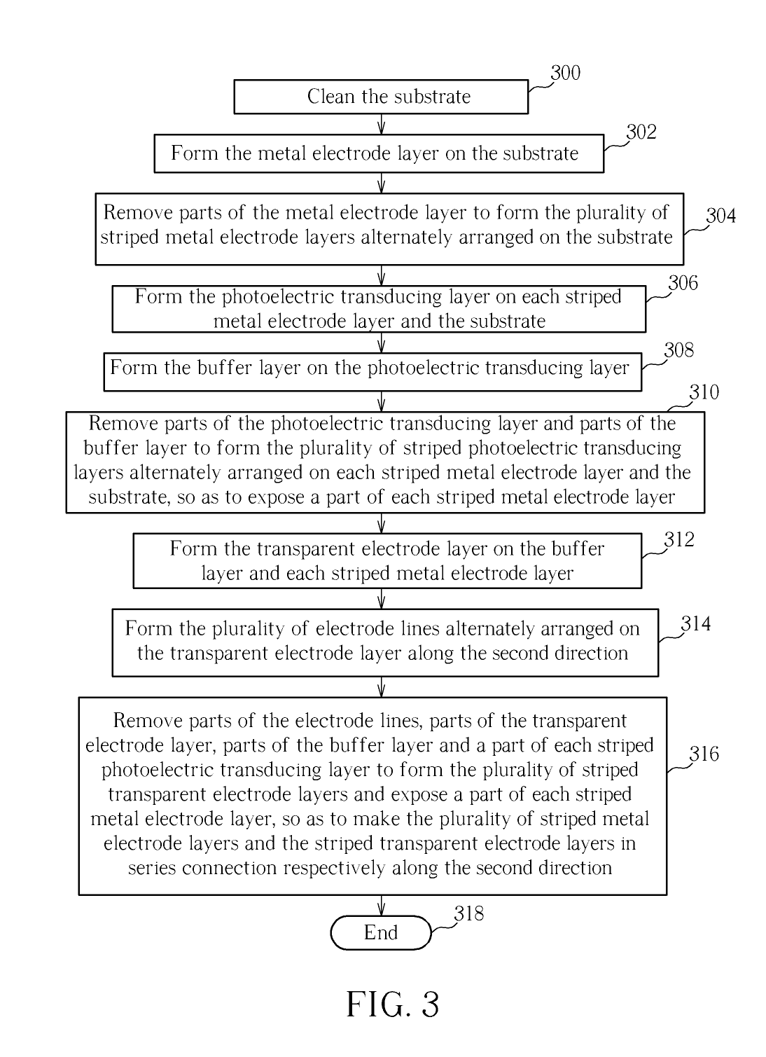

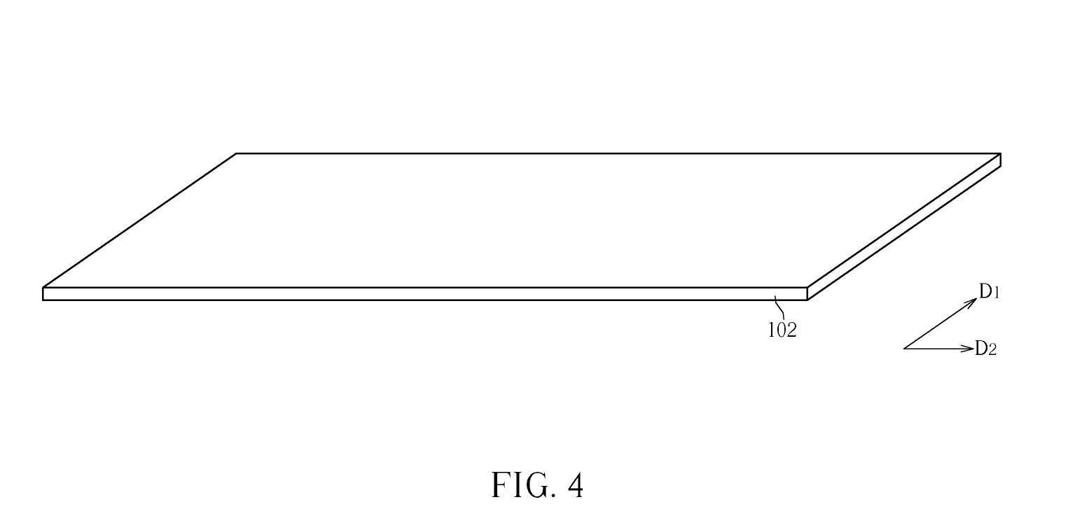

Please refer to FIG. 2 and FIGS. 3-11. FIG. 3 is a flowchart of a method for manufacturing the solar battery module 100 in FIG. 2. FIGS. 4-11 are sectional views of the solar battery module 100 along the second direction D₂ in different procedures in FIG. 2. The method includes the following steps.

Step 300: Clean the substrate 102;

Step 302: Form a metal electrode layer 103 on the substrate 102;

Step 304: Remove parts of the metal electrode layer 103 to form the plurality of striped metal electrode layers 104 alternately arranged on the substrate 102;

Step 306: Form a photoelectric transducing layer 105 on each striped metal electrode layer 104 and the substrate 102;

Step 308: Form the buffer layer 110 on the photoelectric transducing layer 105;

Step 310: Remove parts of the photoelectric transducing layer 105 and parts of the buffer layer 110 to form the plurality of striped photoelectric transducing layers 106 alternately arranged on each striped metal electrode layer 104 and the substrate 102, so as to expose a part of each striped metal electrode layer 104;

Step 312: Form a transparent electrode layer 107 on the buffer layer 110 and each striped metal electrode layer 104;

Step 314: Form the plurality of electrode lines 109 alternately arranged on the transparent electrode layer 107 along the second direction D₂;

Step 316: Remove parts of the electrode lines 109, parts of the transparent electrode layer 107, parts of the buffer layer 110 and a part of each striped photoelectric transducing layer 106 to form the plurality of striped transparent electrode layers 108 alternately arranged on the buffer layer 110 and the each striped metal electrode layer 104 and expose a part of each striped metal electrode layer 104, so as to make the plurality of striped metal electrode layers 104 and the striped transparent electrode layers 108 in series connection respectively along the second direction D₂;

Step 318: End.

More detailed description for the said steps is introduced as follows. In Step 300, the substrate 102 in FIG. 4 is cleaned for preventing dirt from heaping on the substrate 102. At this time, a blocking layer made of Al₂O₃ or SiO₂ material could be selectively formed on the substrate 102, for preventing crystallization of the photoelectric transducing layer 105 from being influenced by diffusion of impurity in the substrate 102. Furthermore, NaF material could be formed on the transparent substrate 102 by an evaporation processor a sputtering process for crystallizing the light absorber film on the substrate 102.

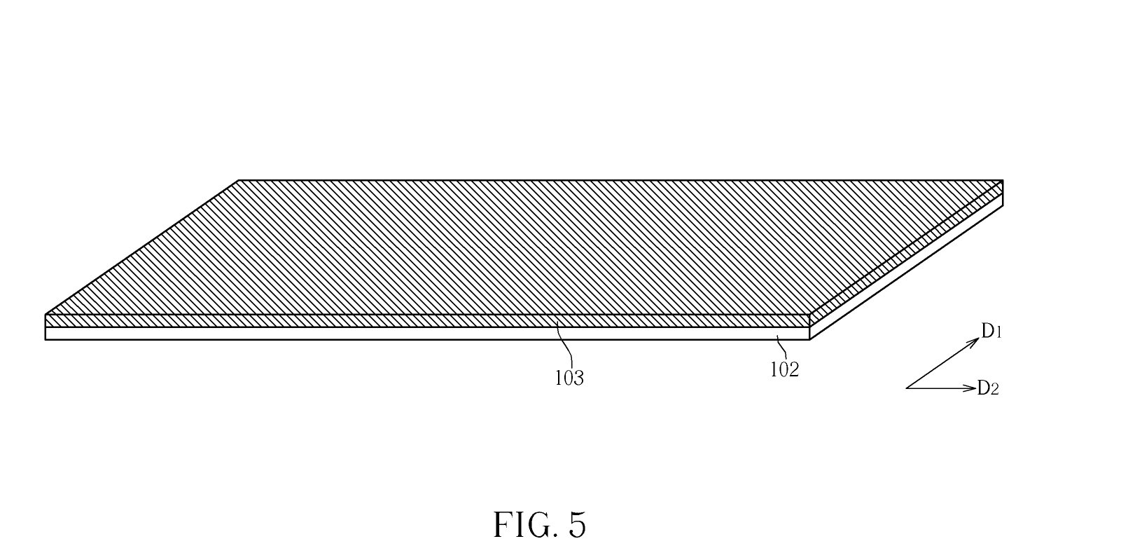

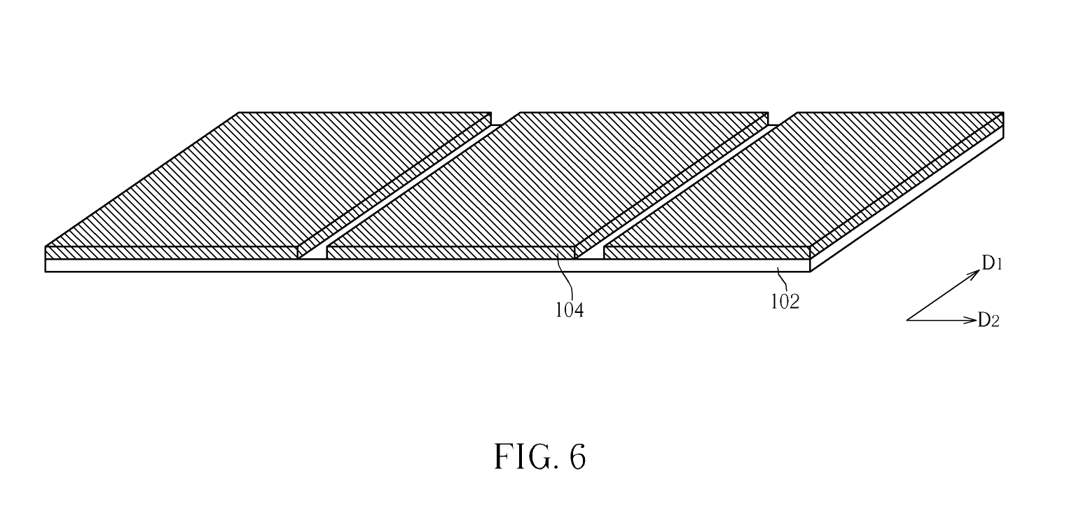

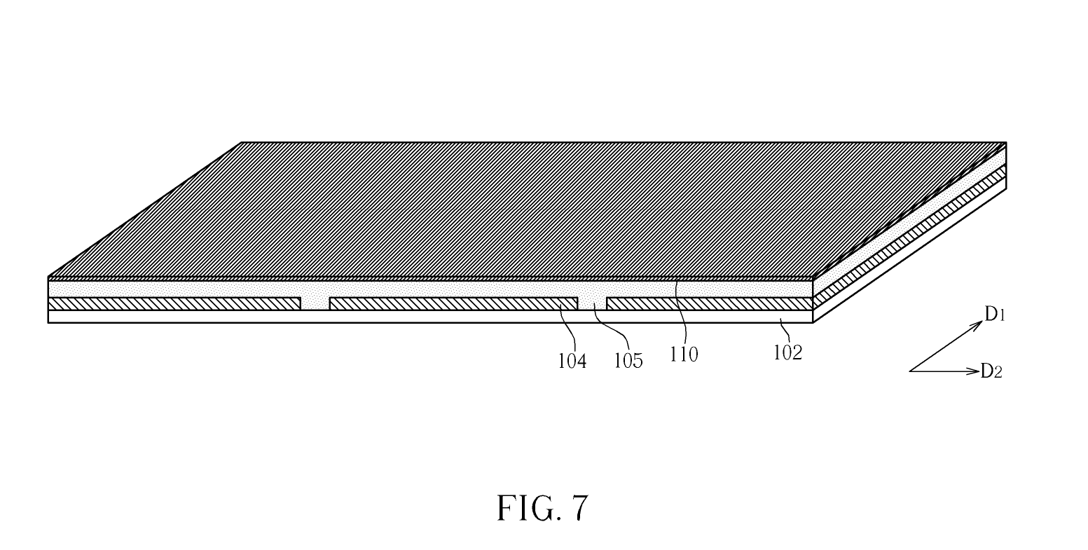

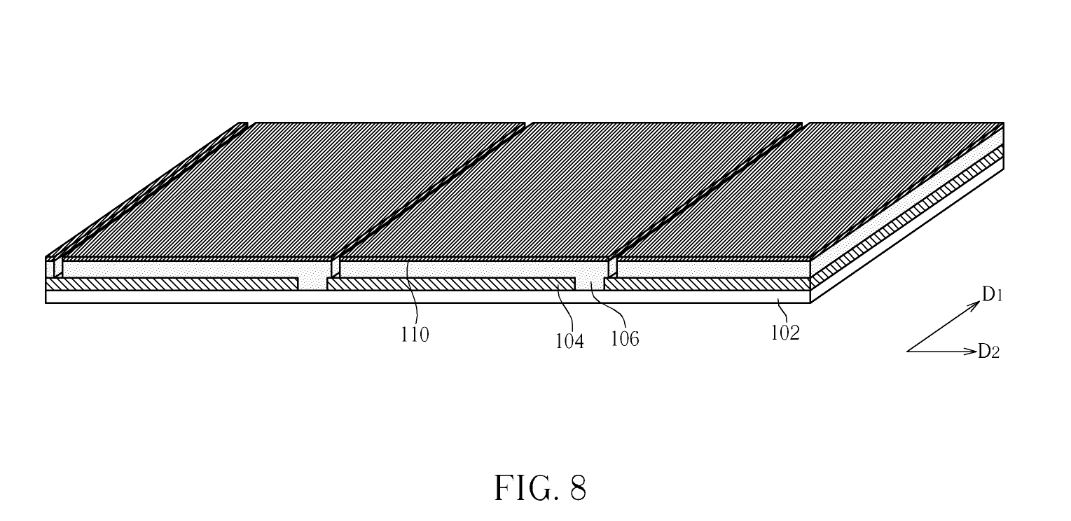

Subsequently, as shown in FIG. 5, the metal electrode layer 103 could be formed on the substrate 102 by a sputtering process (Step 302), and the parts of the metal electrode layer 103 could be then removed by laser or other removing technology (Step 304) to expose parts of the substrate 102 and form the plurality of striped metal electrode layers 104 alternately arranged on the substrate 102 (as shown in FIG. 6). Next, as shown in FIG. 7, the photoelectric transducing layer 105 could be formed on the plurality of striped metal electrode layers 104 and the exposed parts of the substrate 102 by a thin film deposition process (Step 306), and the buffer layer 110 is then formed on the photoelectric transducing layer 105 by a thin film deposition process (Step 308). Subsequently, as shown in FIG. 8, a scraper or other removing technology is utilized to remove the parts of the photoelectric transducing layer 105 and the parts of the buffer layer 110 along the first direction D₁ to form the plurality of striped photoelectric transducing layers 106 (Step 310), so as to expose the part of the each striped metal electrode layer 104. In general, the photoelectric transducing layer 105 could be formed by a co-evaporation process, a vacuum sputter process, or a selenization process, and the buffer layer 110 could be formed by a chemical bath deposition process, so as to enhance the photoelectric transducing efficiency of the solar battery module 100.

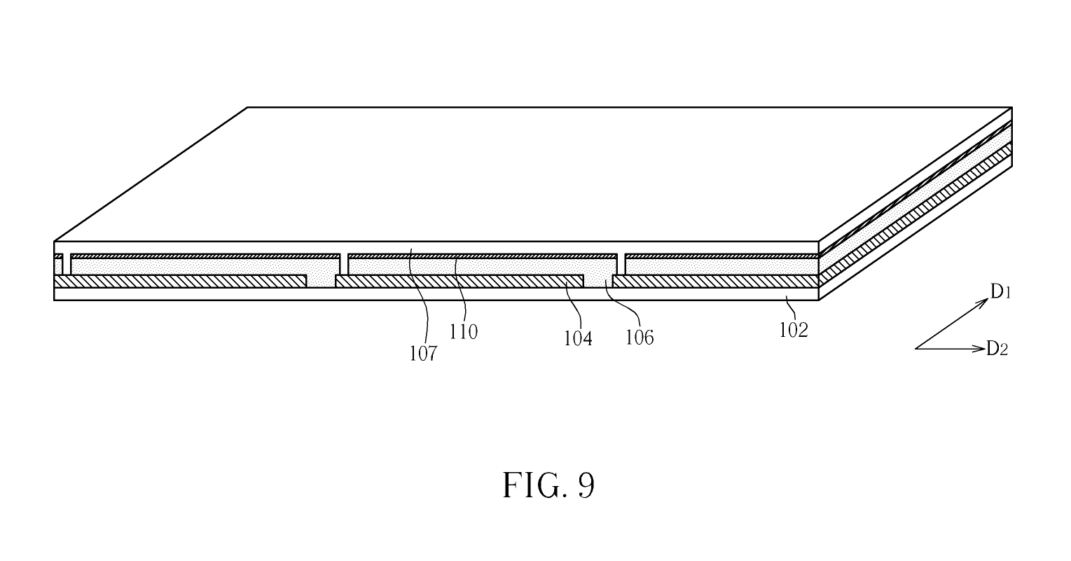

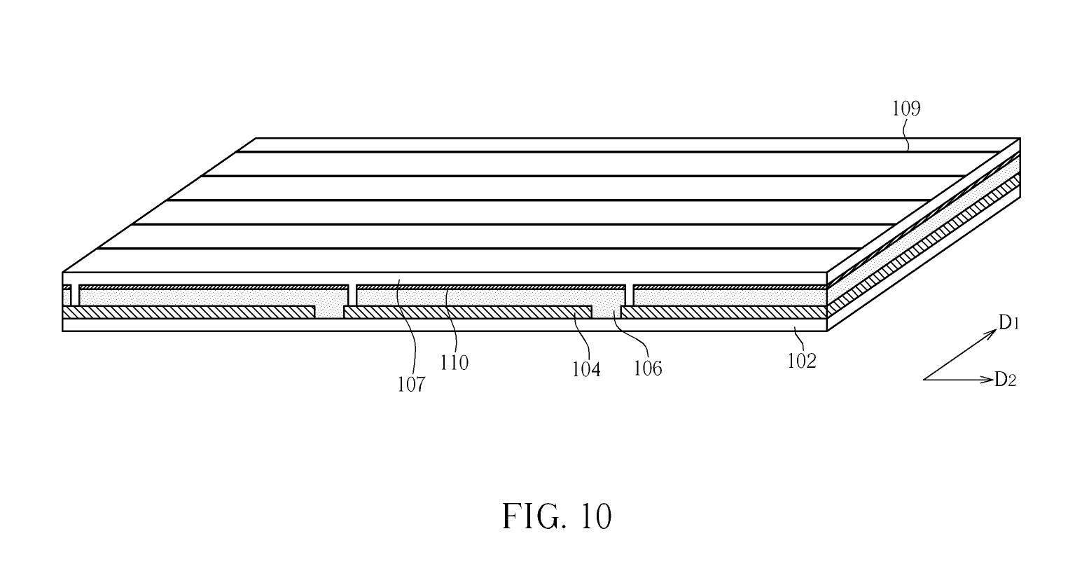

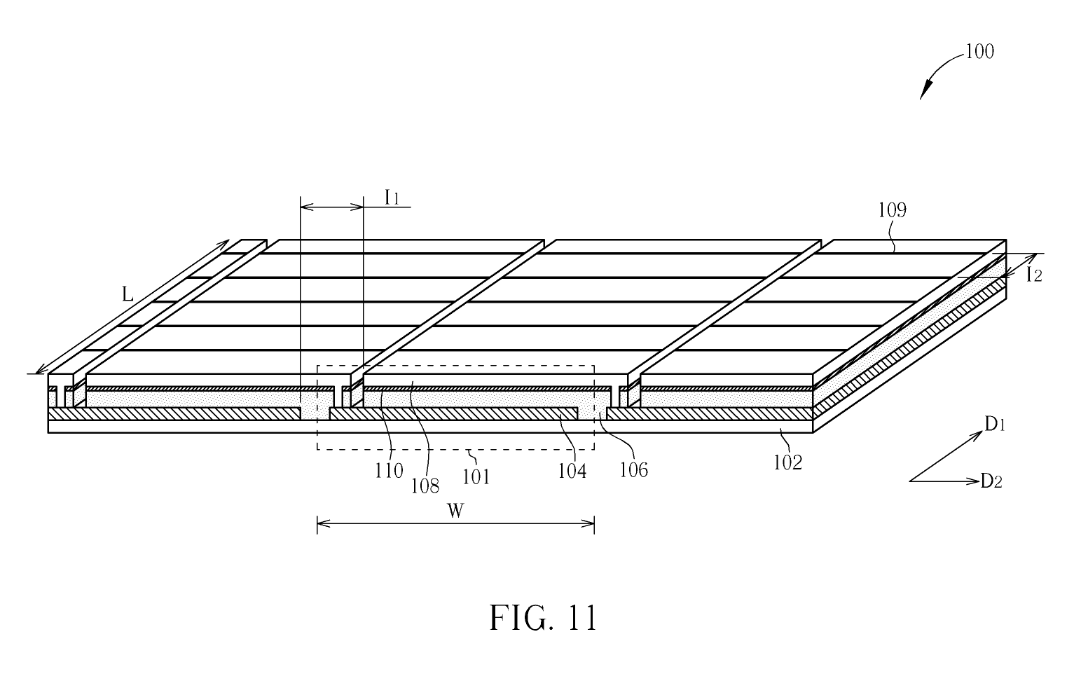

Next, as shown in FIG. 9, FIG. 10, and FIG. 11, after the transparent electrode layer 107 is formed on the buffer layer 110 and the striped metal electrode layers 104 (Step 312), the plurality of electrode lines 109 are formed alternately on the transparent electrode layer 107 along the second direction D₂ (Step 314), wherein forming of the electrode lines 109 is preferably performed by a printing process, but is not limited thereto. Finally, the parts of the electrode lines 109, the parts of the transparent electrode layer 107, the parts of the buffer layer 110, and the part of each striped photoelectric transducing layer 106 are removed along the first direction D₁ by a scraper or other removing technology, to form the plurality of striped transparent electrode layers 108 and expose the part of each striped metal electrode layer 104 (Step 316), so that the plurality of striped metal electrode layers 104 and the plurality of striped transparent electrode layers 108 could be in series connection along the second direction D₂. Accordingly, the solar battery module 100 could include the plurality of solar batteries 101 in series connection to generate a greater current.

Thus, in the design in which the width of each solar battery 101 is increased to reduce the areas of the striped photoelectric transducing layers 106, which are needed to remove, the present invention could utilize the electrode lines 109 on the striped transparent electrode layers 108 as auxiliary electrodes for current collection, to solve the problem that the overall photoelectric transducing efficiency of the solar battery module 100 is decreased due to increase of the resistance of the striped transparent electrode layer 108. Furthermore, since there is no need to additionally increase the thickness of the striped transparent electrode layer 108, the present invention could further avoid the problem that the overall photoelectric transducing efficiency of the solar battery module 100 is influenced due to decrease of the transmittance of the striped transparent electrode layer 108.

Besides, the present invention could further improve the overall photoelectric transducing efficiency of the solar battery module 100. For example, please refer to FIG. 11. In this example, it is assumed that the solar battery module 100 is consisted of one hundred and eight solar batteries 101 in series connection and a length L of the solar battery module 100 is equal to 121 cm. Furthermore, in general, a width W of the solar battery 101 is between 4 mm and 6.5 mm, and an interval I₁ between the corresponding striped transparent electrode layer 108 on each striped metal electrode layer 104 and the adjacent striped metal electrode layer 104 is approximately equal to 0.5 mm. Plus, as mentioned above, the width of each electrode line 109 is preferably less than the interval I₁ between the corresponding striped transparent electrode layer 108 on each striped metal electrode layer 104 and the adjacent s striped metal electrode layer 104, and an interval I₂ between two adjacent electrode lines 109 is, for example, equal to 11 mm. Thus, it is further assumed that the width W of the solar battery 101 is equal to 5.5 mm, the interval I₁ between the corresponding striped transparent electrode layer 108 on each striped metal electrode layer 104 and the adjacent striped metal electrode layer 104 is equal to 0.5 mm, the width of each electrode line 109 is equal to 50 μm, and the interval I₂ between two adjacent electrode lines 109 is equal to 11 mm. In other words, in this example, there are one hundred and ten electrode lines 109 formed on each striped transparent electrode layer 108.

According to the aforesaid assumptions, if the width W of each solar battery 101 is increased to 11 mm for reducing the areas of the striped photoelectric transducing layers 106, which are needed to remove, the solar battery module 100 is consisted of fifty and four solar batteries 104 in series connection instead. In such a manner, the saved areas of the striped photoelectric transducing layers 106 due to increase of the width W of each solar battery 101 are equal to 54*0.5 mm*121 cm, and the inactive areas of the striped photoelectric transducing layers 106 covered by the electrode lines 109 are approximately equal to 54*50 μm*11 mm*110. That is, the saved areas of the striped photoelectric transducing layers 106 due to increase of the width W of each solar battery 101 is approximately ten times the inactive areas of the striped photoelectric transducing layers 106 covered by the electrode lines 109.

on the premise that the width of each electrode line 109 is less than the interval I₁ between the corresponding striped transparent electrode layer 108 on each striped metal electrode layer 104 and the adjacent striped metal electrode layer 104 and number of the electrode lines 109 is appropriately controlled, even if forming of the electrode lines 109 may reduce the photoelectric transducing area of each striped photoelectric transducing layer 106, the saved areas of the striped photoelectric transducing layers 106 due to increase of the width W of each solar battery 101 could be still greater than the inactive areas of the striped photoelectric transducing layers 106 covered by the electrode lines 109. Thus, the present invention could efficiently increase the effective photoelectric transducing area of each striped photoelectric transducing layer 106, so as to improve the photoelectric transducing efficiency of the solar battery module 100.

To be noted, material and manufacturing procedures of the buffer layer 110 are not limited to the above-mentioned embodiment, meaning that Step 308 is a selectable procedure. Furthermore, Step 312 and Step 314 could be exchanged. That is, in another embodiment, the plurality of electrode lines 109 could be first formed on the buffer layer 110 along the second direction D₂, and then the transparent electrode layer 107 could be formed on the buffer layer 110 and each striped metal electrode layer 104. In other words, in this embodiment, the electrode lines 109 are formed between the buffer layer 110 and the striped transparent electrode layers 108.

In the design in which the width of the solar battery is increased for reducing the area of the striped photoelectric transducing layer, which is needed to remove, the present invention utilizes the electrode lines as auxiliary electrodes for current collection, so as to solve the problem that the overall photoelectric transducing efficiency of the solar battery module is decreased due to increase of the resistance of the striped transparent electrode layer. Furthermore, since there is no need to additionally increase the thickness of the striped transparent electrode layer for reducing the resistance of the striped transparent electrode layer, the present invention could further avoid the problem that the overall photoelectric transducing efficiency of the solar battery module is influenced by decrease of transmittance of the striped transparent electrode layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A solar battery module comprising:
a substrate;
a plurality of striped metal electrode layers formed alternately on the substrate along a first direction;
a plurality of striped photoelectric transducing layers, each striped photoelectric transducing layer being formed on the corresponding striped metal electrode layer and the substrate along the first direction;
a plurality of striped transparent electrode layers, each striped transparent electrode layer being formed on the corresponding striped metal electrode layer and the corresponding striped photoelectric transducing layer along the first direction, the plurality of striped transparent electrode layers and the plurality of striped metal electrode layers being in series connection along a second direction; and
a plurality of electrode lines formed alternately on each striped transparent electrode layer or between each striped photoelectric transducing layer and each striped transparent electrode layer along the second direction;
wherein a width of each electrode line is less than an interval between the striped transparent electrode layer on each striped metal electrode layer and the adjacent striped metal electrode layer.

2. The solar battery module of claim 1, wherein The width of each electrode line is less than 500 μm.

3. The solar battery module of claim 1, wherein an interval between two adjacent electrode lines is less than or equal to 13 mm.

4. The solar battery module of claim 1 further comprising:
a buffer layer formed on each striped photoelectric transducing layer.

5. The solar battery module of claim 1, wherein the plurality of striped metal electrode layer is made of molybdenum (Mo) material, Tantalum (Ta) material, Titanium (Ti) material, Vanadium (V) material, or Zirconium (Zr) material.

6. The solar battery module of claim 1, wherein the plurality of striped photoelectric transducing layers is a chalcopyrite structure.

7. The solar battery module of claim 1, wherein the plurality of striped transparent electrode layer is a transparent conductive layer made of aluminum zinc oxide (AZO) or tin-doped indium oxide (ITO) material.

8. The solar battery module of claim 1, wherein the first direction is substantially perpendicular to the second direction.

9. A method for manufacturing a solar battery module, the method comprising:
forming a metal electrode layer on a substrate;
removing parts of the metal electrode layer along a first direction to form a plurality of striped metal electrode layers alternately arranged on the substrate;
forming a photoelectric transducing layer on each striped metal electrode layer and the substrate;
removing parts of the photoelectric transducing layer along the first direction to form a plurality of striped photoelectric transducing layers alternately arranged on the each striped metal electrode layer and the substrate, so as to expose a part of each striped metal electrode layer;
forming a plurality of electrode lines alternately arranged on each striped photoelectric transducing layer along a second direction;
forming a transparent electrode layer on each striped photoelectric transducing layer and each electrode line; and
removing parts of the transparent electrode layer, parts of the electrode lines, and a part of each striped photoelectric transducing layer along the first direction to form a plurality of striped transparent electrode layers alternately arranged on each striped photoelectric transducing layer and each electrode line and expose apart of each striped metal electrode layer, so as to make the plurality of striped metal electrode layers and the plurality of striped transparent electrode layers in series connection along the second direction.

10. The method of claim 9 further comprising:
forming a buffer layer on the photoelectric transducing layer.

11. The method of claim 9, wherein removing the parts of the metal electrode layer along the first direction to form the plurality of striped metal electrode layers alternately arranged on the substrate comprises:
removing the parts of the metal electrode layer along the first direction by laser to form the plurality of striped metal electrode layers alternately arranged on the substrate.

12. The method of claim 9, wherein removing the parts of the photoelectric transducing layer along the first direction to form the plurality of striped photoelectric transducing layers alternately arranged on the each striped metal electrode layer and the substrate comprises:
utilizing a scraper to remove the parts of the photoelectric transducing layer along the first direction to form the plurality of striped photoelectric transducing layers alternately arranged on the each striped metal electrode layer and the substrate.

13. The method of claim 9, wherein removing the parts of the transparent electrode layer, the parts of the electrode lines, and the part of each striped photoelectric transducing layer along the first direction comprises:
utilizing a scraper to remove the parts of the transparent electrode layer, the parts of the electrode lines, and the part of each striped photoelectric transducing layer along the first direction.
